(19) United States
(12) Patent Application Publication
(10) Pub. No.: US 2024/0157391 A1
(43) Pub. Date: May 16, 2024

(54) LIQUID SUPPLY UNIT AND SUBSTRATE TREATING APPARATUS INCLUDING SAME

(71) Applicant: SEMES CO., LTD., Cheonan-si (KR)

(72) Inventors: Sung Jin BANG, Cheonan-si (KR); Chang Suk OH, Cheonan-si (KR)

(73) Assignee: SEMES CO., LTD., Cheonan-si (KR)

(21) Appl. No.: 18/382,525

(22) Filed: Oct. 22, 2023

(30) Foreign Application Priority Data
Nov. 11, 2022 (KR) 10-2022-0150706

(51) Int. Cl. B05C 5/02

(52) U.S. Cl. CPC B05C 5/027; B05C 5/0208

(57) ABSTRACT

Proposed is a substrate treating apparatus. The substrate treating apparatus includes a treating container having a treating space therein, a support unit supporting and rotate a substrate in the treating space, and a liquid supply unit supplying a treating liquid onto the substrate, wherein the liquid supply unit may include a nozzle member and an actuator for moving the nozzle member, wherein the nozzle member may include nozzles arranged along a first direction so that the nozzles form a first row and nozzles coupled to the body and arranged along the first direction so that the nozzles form a second row, wherein the first row and the second row may be spaced apart from each other in a second direction perpendicular to the first direction when viewed from above. At this time, the nozzles constituting the nozzle member may be observed as a whole from the front.

### CROSS REFERENCE TO RELATED APPLICATION

The present application claims priority to Korean Patent Application No. 10-2022-0150706, filed Nov. 11, 2022, the entire contents of which is incorporated by reference herein for all purposes.

### BACKGROUND OF THE INVENTION

### 1. Field of the Invention

The present disclosure relates to a liquid supply unit and a substrate treating apparatus including the same.

### 2. Description of the Related Art

In order to manufacture semiconductor devices, various processes such as cleaning, deposition, photolithography (photo), etching, and ion implantation are performed. Among them, the photo process includes: coating for forming a film by applying a photoresist on the surface of a substrate; exposure for transferring a circuit pattern to the film formed on the substrate; and development for selectively removing the film formed on the substrate from an exposed area or the opposite area.

In the step of coating, a process of discharging a photoresist after discharging a pre-wetting liquid on a substrate is performed. The photoresist discharged on the substrate differs in the composition ratio of the materials constituting the photoresist according to the conditions required by the process. A nozzle capable of ejecting photoresists with different characteristics is needed in the recent trend of multi-layered and large-sized substrates. However, in order to discharge photoresists having different characteristics onto a substrate and to increase productivity for large-sized substrates, the number of nozzles need to be increased. As the number of nozzles increases, enlarging the size of a nozzle member made up of the nozzles is inevitable.

When the nozzle member is enlarged, the space occupied by the nozzle member in a device for supplying liquid onto a substrate may become relatively large. This makes maintenance for the liquid supply device difficult. Moreover, other components included in the liquid supply device are subject to spatial restrictions, and interference with other components may occur when the nozzle moves.

### SUMMARY OF THE INVENTION

Accordingly, the present disclosure has been made keeping in mind the above problems occurring in the related art, and the present disclosure is intended to provide a liquid supply unit and a substrate treating apparatus including the same, capable of increasing substrate treating efficiency.

In addition, an objective of the present disclosure is to provide a liquid supply unit and a substrate treating apparatus including the same, capable of discharging photoresists having different characteristics onto a substrate.

In addition, an objective of the present disclosure is to provide a liquid supply unit and a substrate treating apparatus including the same, capable of efficient nozzle inspection by arranging individual nozzles so that the entire image of a nozzle member may be acquired with just a single shot in the shooting process for checking the defective state of the nozzle member.

Objectives of the present disclosure are not limited thereto, and other objectives not mentioned will be clearly understood by those skilled in the art from the following description.

In order to achieve the above objective, according to an embodiment of the present disclosure, there is provided a liquid supply unit including: a nozzle member configured to supply a treating liquid onto a substrate; and an actuator configured to move the nozzle member. The nozzle member may include: a body; a first group of nozzles coupled to the body and arranged along a first direction so that the nozzles form a first row; and a second group of nozzles coupled to the body and arranged along the first direction so that the nozzles form a second row, wherein the first row and the second row may be spaced apart from each other by a predetermined distance in the first direction and a second direction perpendicular to the first direction when viewed from above, so that the first group of nozzles and the second group of nozzles do not overlap each other when the nozzle member is viewed from the front.

According to an embodiment of the present disclosure, there is provided a substrate treating apparatus, including: a treating container configured to have a treating space therein; a support unit configured to support a substrate in the treating space; and a liquid supply unit configured to supply a treating liquid onto the substrate. The liquid supply unit may include: a nozzle member movably provided by an actuator, wherein the nozzle member may include: a body; a first group of nozzles coupled to the body and arranged along a first direction so that the nozzles form a first row; and a second group of nozzles coupled to the body and arranged along the first direction so that the nozzles form a second row, wherein the first row and the second row may be spaced apart from each other by a predetermined distance in the first direction and a second direction perpendicular to the first direction when viewed from above, so that the first group of nozzles and the second group of nozzles do not overlap each other when the nozzle member is viewed from the front.

According to an embodiment of the present disclosure, there is provided substrate treating equipment, including: an index module where a substrate is carried in or out; and a treating module configured to include a substrate treating apparatus performing a liquid treating process on the substrate. The substrate treating apparatus may include: treating containers arranged in a line and having support units for supporting substrates disposed in an internal space thereof; and a liquid supply unit supplying a treating liquid onto the substrate, wherein the liquid supply unit may include: a nozzle member that is moved, by an actuator, in a direction in which the treating containers are arranged, wherein the nozzle member may include: a body; a first group of nozzles coupled to the body and arranged along a first direction so that the nozzles form a first row; and a second group of nozzles coupled to the body and arranged along the first direction so that the nozzles form a second row, wherein the first row and the second row may be spaced apart from each other by a predetermined distance in the first direction and a second direction perpendicular to the first direction when viewed from above, so that the first group of nozzles and the second group of nozzles do not overlap each other when the nozzle member is viewed from the front.

According to embodiments of the present disclosure, it is possible to increase substrate treating efficiency by improving substrate productivity.

Furthermore, according to the embodiments of the present disclosure, it is possible to discharge photoresists having different characteristics onto a substrate through a single nozzle member.

Furthermore, according to the embodiments of the present disclosure, it is possible to minimize interference between the nozzle member discharging a treating liquid and other members adjacent to the nozzle member, and to minimize the equipment installation area.

Furthermore, according to the embodiments of the present disclosure, it is possible to reduce inspection time and maintenance time of the nozzle member.

The effects of the present disclosure are not limited to the above effects, and effects not mentioned will be clearly understood by those skilled in the art from this specification and the accompanying drawings.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a substrate treating facility according to an embodiment of the present disclosure;

FIG. 2 is a front view of the substrate treating apparatus showing a coating block or development block of FIG. 1;

FIG. 3 is a plan view of the substrate treating apparatus of FIG. 1;

FIG. 4 is a view showing an example of a hand provided in a transport chamber of FIG. 3;

FIG. 5 is a plan view schematically showing an example of a heat treating chamber of FIG. 3;

FIG. 6 is a front view of FIG. 5;

FIG. 7 is a view schematically showing an example of a liquid treating chamber of FIG. 3;

FIG. 8 is a plan view schematically showing a liquid supply unit of FIG. 7 viewed from above;

FIG. 9 is a front view schematically showing a state in which the liquid supply unit of FIG. 7 is viewed from the front;

FIG. 10 is a view from the top of supplying a treating liquid to a substrate using a first group of nozzles of FIG. 7;

FIG. 11 is a view from the top of supplying a treating liquid to a substrate using a second group of nozzles of FIG. 7; and

FIG. 12 is a view schematically showing a nozzle member positioned between a first liquid treating chamber and a second liquid treating chamber of FIG. 3.

### DETAILED DESCRIPTION OF THE INVENTION

Hereinafter, embodiments of the present disclosure will be described in detail with reference to the accompanying drawings. The embodiments of the present disclosure may be modified in various forms, and the scope of the present disclosure should not be construed as being limited due to the embodiments described below. These embodiments are provided to more completely explain the present disclosure to those skilled in the art. Therefore, the shapes of components in the drawings are exaggerated to emphasize a clearer explanation.

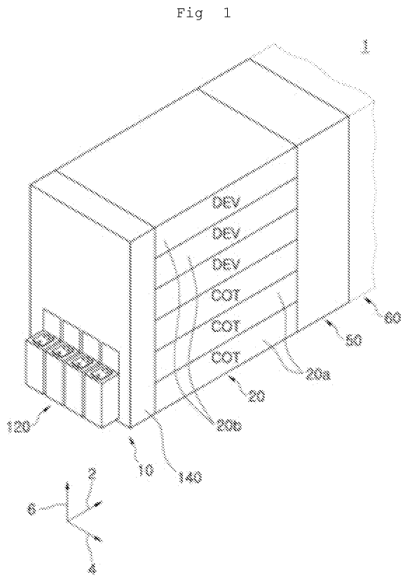

Hereinafter, an embodiment of the present disclosure will be described in detail with reference to FIGS. 1 to 12. In the following embodiment, a process of applying a photoresist on a substrate with a substrate treating apparatus and developing the substrate after exposure will be described as an example. However, the present disclosure is not limited thereto, and may be applied to various types of devices for treating a substrate by supplying a liquid to a rotating substrate. For example, the substrate treating apparatus may be a device that performs a process of supplying a cleaning solution to a substrate to remove foreign substances on the substrate or supplying a chemical solution to the substrate to remove a thin film from the substrate.

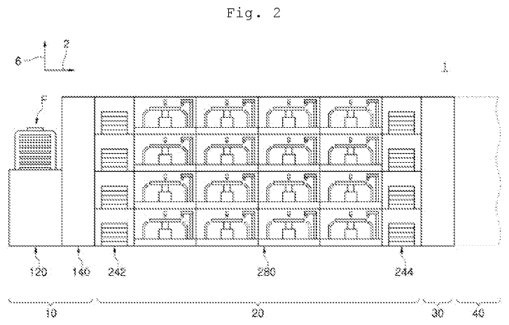

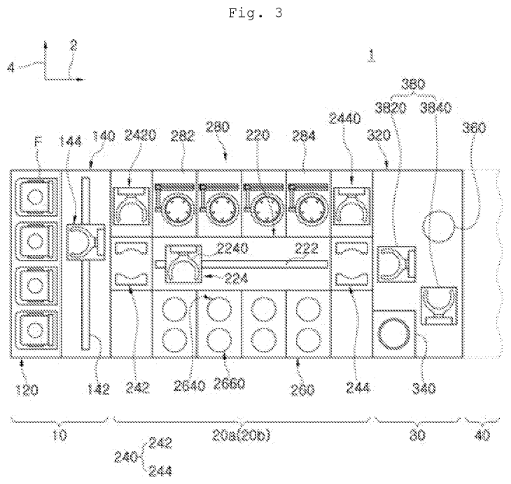

FIG. 1 is a substrate treating facility according to an embodiment of the present disclosure; FIG. 2 is a front view of the substrate treating apparatus showing a coating block or development block of FIG. 1; and FIG. 3 is a plan view of the substrate treating apparatus of FIG. 1.

Referring to FIGS. 1 to 3, a substrate treating facility 1 includes: an index module 10, a treating module 20, and an interface module 30. According to an embodiment, the index module 10, the treating module 20, and the interface module 30 are sequentially arranged in a line. Hereinafter, a direction in which the index module 10, the treating module 20, and the interface module 30 are arranged is defined as a first direction 2, a direction perpendicular to the first direction 2 is defined as a second direction 4 when viewed from above, and a direction perpendicular to the plane including both the first direction 2 and the second direction 4 is defined as a third direction 6.

The index module 10 transfers a substrate W from a container F in which the substrate W is stored to the treating module 20 that treats the substrate W. The index module 10 stores the substrate W, which has been treated in the treating module 20, into the container F. The longitudinal direction of the index module 20 is provided as the second direction 4. The index module 10 has a load port 120 and an index frame 140.

The container F containing the substrate W is seated in the load port 120. The load port 120 is located on the opposite side of the treating module 20 with respect to the index frame 140. A plurality of load ports 120 may be provided, and the plurality of load ports 120 may be arranged in a line along the second direction 4. The number of load ports 120 may increase or decrease depending on process efficiency and footprint conditions of the treating module 20.

The container F is formed with a plurality of slots (not shown) for accommodating substrates W in a state in which the substrates W are arranged horizontally with respect to the ground. As the container F, an airtight container such as a front opening unified pod (FOUP) may be used. The container F may be placed in the load port 120 by a transport means (not shown) such as an overhead transfer, overhead conveyor, or automatic guided vehicle or by an operator.

Inside the index frame 140, an index rail 142 and an index robot 144 are provided. The index rail 142 is provided in the index frame 140 with its longitudinal direction along the second direction 4. The index robot 144 may transport the substrates W. The indexing robot 144 may transport the substrates W between the indexing module 10 and a buffer chamber 240 to be described later. The index robot 144 may include an index hand 1440. The substrate W may be placed on the index hand 1440. The index hand 1440 may include an index base 1442 having an annular ring shape in which a part of the circumference thereof is symmetrically bent, and an index support 1444 for moving the index base 1442. The configuration of the index hand 1440 is the same as or similar to that of a transport hand 2240 described later. The index hand 1440 may be provided to be movable along the second direction 4 on the index rail 142. Accordingly, the index hand 1440 may move forward and backward along the index rail 142. In addition, the index hand 1440 may be provided to be rotatable about an axis parallel to the third direction 6 and movable along the third direction 6.

The treating module 20 receives the substrate W stored in the container F and performs a coating process and a developing process on the substrate W. The treating module 20 has a coating block 20a and a developing block 20b. The coating block 20a performs a coating process on the substrate, and the developing block 20b performs a developing process on the substrate. A plurality of coating blocks 20a are provided, and the coating blocks 20a are provided stacked on top of each other. A plurality of developing blocks 20b are provided, and the developing blocks 20b are provided stacked on top of each other.

According to the embodiment of FIG. 1, two coating blocks 20a are provided and two developing blocks 20b are provided. The coating blocks 20a may be disposed below the developing blocks 20b. As an example, the two coating blocks 20a may perform the same process and be provided with the same structure. In addition, the two developing blocks 20b may perform the same process and be provided with the same structure.

Referring to FIG. 3, the coating block 20a has a transport chamber 220, a buffer chamber 240, a heat treating chamber 260, and a liquid treating chamber 280. The transport chamber 220 provides a space for transporting the substrates W between the buffer chamber 240 and the heat treating chamber 260, between the buffer chamber 240 and the liquid treating chamber 280, and between the heat treating chamber 260 and the liquid treating chamber 280. The buffer chamber 240 provides a space in which the substrates W carried into the coating block 20a and the substrates W exported from the coating block 20a temporarily stay. The heat treating chamber 260 performs a thermal process on the substrate. The thermal process may include a cooling process and a heating process. The liquid treating chamber 280 supplies liquid to the substrate W to form a liquid film. The liquid film may be a photoresist film or an anti-reflection film.

The transport chamber 220 may be provided in the first direction 2 in its longitudinal direction. A guide rail 222 and a transport robot 224 are provided in the transport chamber 220. The guide rail 222 is provided in the transport chamber 220 with its longitudinal direction in the first direction 2. The transport robot 224 may be provided to be linearly movable along the first direction 2 on the guide rail 222. The transport robot 224 transports the substrates W between the buffer chamber 240 and the heat treating chamber 260, between the buffer chamber 240 and the liquid treating chamber 280, and between the heat treating chamber 260 and the liquid treating chamber 280.

As an example, the transport robot 224 has a transport hand 2240 on which the substrate W is placed. The transport hand 2240 may move forward and backward, rotate about an axis parallel to the third direction 6, and move along the third direction 6.

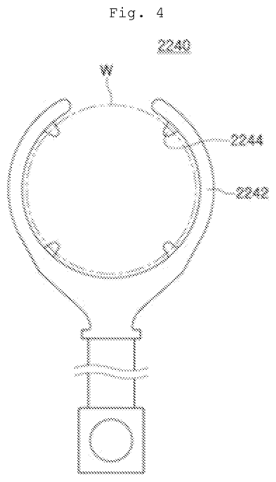

FIG. 4 is a view showing an example of a hand provided in a transport chamber of FIG. 3.

Referring to FIG. 4, the transport hand 2240 has a base 2242 and a support protrusion 2244. The base 2242 may have an annular ring shape in which a part of the circumference thereof is bent. The base 2242 may have a ring shape in which a part of the circumference thereof is symmetrically bent. The base 2242 has an inner diameter larger than the diameter of the substrate W. The support protrusion 2244 extends inwardly from base 2242. A plurality of support protrusions 2244 are provided and support the edge area of the substrate W. As an example, four support protrusions 2244 may be provided at equal intervals.

Referring back to FIGS. 2 and 3, a plurality of buffer chambers 240 are provided. Some of the buffer chambers 240 are disposed between the index module 10 and the transport chamber 220. Hereinafter, these buffer chambers are defined as a front buffer 242. The front buffer 242 is provided in plurality, and may be positioned to be stacked on each other along the vertical direction. The other buffer chambers 240 are disposed between the transport chamber 220 and the interface module 30. Hereinafter, these buffer chambers are defined as a rear buffer 244. The rear buffer 244 is provided in plurality, and may be positioned to be stacked on each other along the vertical direction. Each of the front buffers 242 and the rear buffers 244 temporarily stores a plurality of substrates W. The substrates W stored in the front buffer 242 are carried in or out by the index robot 144 and the transport robot 224. The substrates W stored in the rear buffer 244 are carried in or out by the transport robot 224 and a first robot 3820 to be described later.

Buffer robots 2420 and 2440 may be provided on one side of the buffer chamber 240. The buffer robots 2420 and 2440 may include a front buffer robot 2420 and a rear buffer robot 2440. The front buffer robot 2420 may be provided on one side of the front buffer 242, and the rear buffer robot 2440 may be provided on one side of the rear buffer 244, but is not limited thereto, and the buffer robots 2420 and 2440 may be provided on both sides of the buffer chamber 240.

The front buffer robot 2420 may transport the substrates W between the front buffers 242.

The front end buffer robot 2420 may include a front buffer hand. The front buffer hand may move up and down along the third direction 6. The front buffer hand may be rotated. The front buffer hand may transport the substrate W.

The rear buffer robot 2440 may transport the substrates W between the rear buffers 244. The rear buffer robot 2440 may include a rear buffer hand. The configuration of the rear buffer hand is the same as or similar to that of the front buffer hand. Therefore, the description of the rear buffer hand is omitted.

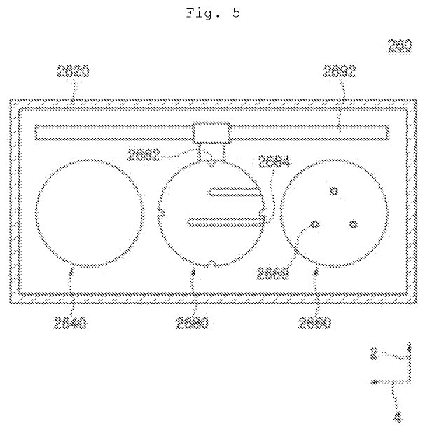

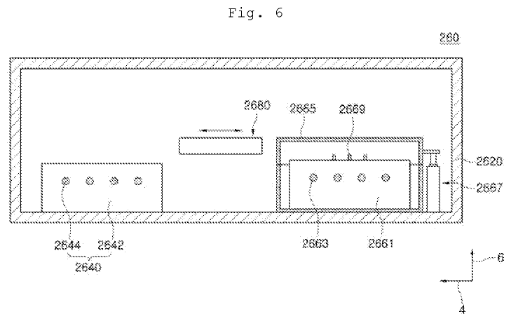

FIG. 5 is a plan view schematically showing an example of a heat treating chamber of FIG. 3; and FIG. 6 is a front view of FIG. 5. Referring to FIGS. 5 and 6, a plurality of heat treating chambers 260 may be provided. The heat treating chambers 260 are disposed along the first direction 2. The heat treating chambers 260 are located on one side of the transfer chamber 220. The heat treating chamber 260 may include a housing 2620, a cooling unit 2640, a heating unit 2660, and a transport plate 2680.

The housing 2620 is generally provided in the shape of a rectangular parallelepiped. The housing 2620 provides space therein. An entrance (not shown) through which the substrate W is in and out is provided on the sidewall of the housing 2620. The entrance may remain open. A door (not shown) may be provided to selectively open and close the entrance.

The cooling unit 2640, the heating unit 2660, and the transport plate 2680 may be provided inside the housing 2620. The cooling unit 2640 and the heating unit 2660 are provided side by side along the second direction 4. As an example, the cooling unit 2640 may be located relatively closer to the transport chamber 220 than the heating unit 2660. The cooling unit 2640 includes a cooling plate 2642. The cooling plate 2642 may have a generally circular shape when viewed from the top. A cooling member 2644 is provided on the cooling plate 2642. As an example, the cooling member 2644 is provided inside the cooling plate 2642 and may be provided as a passage through which cooling fluid flows.

The heating unit 2660 provided in some of the heat treating chambers 260 may improve the adhesion rate of a photoresist to the substrate W by supplying gas while heating the substrate W. As an example, a gas supplied while heating the substrate W may be hexamethyldisilane.

The heating unit 2660 may include a heating plate 2661, a heater 2663, a cover 2665, and an actuator 2667. The heating plate 2661 has a generally circular shape when viewed from the top. The heating plate 2661 may have a larger diameter than the substrate W. The heater 2663 is installed on the heating plate 2661. The heater 2663 may be provided as a heating resistor to which current is applied.

The heating plate 2661 is provided with lift pins 2669 that can be driven in the vertical direction along the third direction 6. The lift pins 2669 receive a substrate W from a transport means outside the heating unit 2660 and place the substrate W on the heating plate 2661, or lift the substrate W from the heating plate 2661 and transfer the substrate W to a transport means outside the heating unit 2660. As an example, three lift pins 2669 may be provided.

The cover 2665 has an open bottom space therein. The cover 2665 is positioned on top of the heating plate 2661 and is moved up and down by the actuator 2667. The cover 2665 is moved so that a space formed by the cover 2665 and the heating plate 2661 serves as a heating space for heating a substrate W.

The transport plate 2680 is generally provided in a disc shape and has a diameter corresponding to that of a substrate W. A notch 2682 is formed at the edge of the transport plate 2680. The notch 2682 is provided in a number corresponding to the support protrusion 2244 formed on the transport hand 2240 of the transport robot 224, and is formed at a position corresponding to the support protrusion 2244. When the vertical position of the transport hand 2240 and the transport plate 2680 is changed at the position where the transport hand 2240 and the transport plate 2680 are vertically aligned, a substrate W is transferred between the transport hand 2240 and the transport plate 2680. The transport plate 2680 is mounted on a guide rail 2692 and may be moved between a first area 2696 and a second area 2698 along the guide rail 2692 by the actuator 2694.

The transport plate 2680 is provided with a plurality of slit-shaped guide grooves 2684.

The guide grooves 2684 extend from the end of the transport plate 2680 to the inside of the transport plate 2680. The guide grooves 2684 are provided along the second direction 4 in their longitudinal direction, and the guide grooves 2684 are spaced apart from each other along the first direction 2. The guide grooves 2684 prevent the transport plate 2680 and the lift pins 2669 from interfering with each other when the transfer of the substrates W is performed between the transport plate 2680 and the heating unit 2660.

Cooling of the substrate W is performed in a state where the transport plate 2680 on which the substrate W is placed is in contact with the cooling plate 2642. The transport plate 2680 is made of a material with high thermal conductivity so that heat may be easily transferred between the cooling plate 2642 and the substrate W.

As an example, the transport plate 2680 may be made of a metal material.

Alternatively, the transport plate 2680 may be provided in a form combined with the cooling unit 2640.

Referring back to FIGS. 2 and 3, a plurality of liquid treating chambers 280 are provided.

Some of the liquid treating chambers 280 may be provided to be stacked on top of each other. The liquid treating chambers 280 are disposed on one side of the transfer chamber 220. The liquid treating chambers 280 are arranged side by side along the first direction 2. Some of the liquid treating chambers 280 are provided adjacent to the index module 10. Hereinafter, the liquid treating chambers 280 are defined as a front liquid treating chamber 282. The other liquid treating chambers 280 are provided adjacent to the interface module 30. Hereinafter, the liquid treating chambers 280 are defined as rear liquid treating chambers 284.

The front liquid treating chamber 282 applies a first liquid on the substrate W, and the rear liquid treating chamber 284 applies a second liquid on the substrate W. The first liquid and the second liquid may be different types of liquids. According to an embodiment, the first liquid is an antireflection film, and the second liquid is a photoresist. The photoresist may be applied on the substrate W coated with the antireflection film.

Alternatively, the first liquid is a photoresist and the second liquid is an antireflection film. In this case, the antireflection film may be applied on the substrate W coated with the photoresist. Alternatively, the first liquid and the second liquid are the same kind of liquid, and they may both be photoresists.

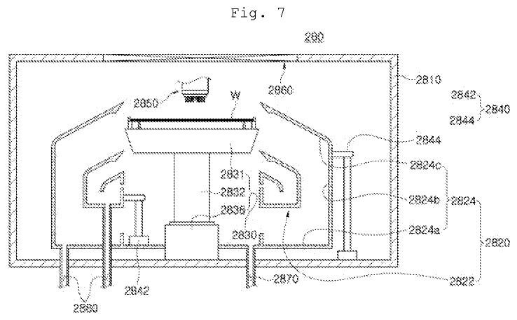

FIG. 7 is a view schematically showing an example of a liquid treating chamber of FIG. 3.

Referring to FIG. 7, the liquid treating chamber 280 includes a housing 2810, a treating container 2820, a support unit 2830, and a liquid supply unit 2850.

The housing 2810 provides a space therein. The housing 2810 is generally provided in a rectangular parallelepiped shape. An opening (not shown) may be formed on one side of the housing 2810. The opening functions as an entrance through which the substrate W is carried into the internal space or taken out of the internal space. In addition, in order to selectively seal the entrance, a door (not shown) may be installed in an area adjacent to the entrance. The door may seal the internal space by blocking the entrance while the substrate W carried into the internal space is being processed.

The treating container 2820, the support unit 2830, and the liquid supply unit 2850 are disposed within the housing 2810.

The treating container 2820 may have a treating space with an open top. The treating container 2820 may be a bowl having a treating space. The internal space may be provided to enclose the treating space. The treating container 2820 may have a cup shape with an open top. The treating space of the treating container 2820 may be a space in which the support unit 2830 to be described later supports and rotates the substrate W. The treating space may be a space in which the liquid supply unit 2850 to be described later supplies fluid to treat the substrate W.

As an example, the treating container 2820 may include an inner cup 2922 and an outer cup 2824. The outer cup 2824 is provided to surround the support unit 2830, and the inner cup 2822 may be positioned inside the outer cup 2824. The inner cup 2822 and the outer cup 2824 may each have an annular ring shape when viewed from above. A space between the inner cup 2822 and the outer cup 2824 may serve as a recovery path through which the fluid introduced into the treating space is recovered.

When viewed from above, the inner cup 2822 may be provided in a shape surrounding a support shaft 2832 of the support unit 2830 to be described later. For example, the inner cup 2822 may be provided in a circular plate shape surrounding the support shaft 2832 when viewed from above. When viewed from the top, the inner cup 2822 may be positioned to overlap an exhaust line 2880, which will be described below, coupled to the housing 2810.

The inner cup 2822 may have an inner portion and an outer portion. Upper surfaces of each of the inner and outer portions may be provided to have different angles based on a virtual horizontal line. For example, when viewed from above, the inner portion may be positioned to overlap a body 2831 of the support unit 2830 to be described later. The inner portion may be positioned facing the support shaft 2832. The upper surface of the inner portion may face an upwardly inclined direction as the distance from the support shaft 2832 increases, and the outer portion may extend outward from the inner portion. The upper surface of the outer portion may face a downwardly inclined direction as the distance from the support shaft 2832 increases. As an example, the point where the outer portion and the inner portion meet may be lower than the upper end of the inner portion. The point where the inner portion and the outer portion meet each other may be rounded. The outer portion may be combined with the outer cup 2824 to form a return path through which treating medium is returned.

The outer cup 2824 may be provided in a cup shape surrounding the support unit 2830 and the inner cup 2822. The outer cup 2824 may include a bottom portion 2824a, a side portion 2824b, and an inclined portion 2824c.

The bottom portion 2824a may have a circular plate shape having a hollow shape. A recovery line 2870 may be connected to the bottom portion 2824a. The recovery line 2870 may recover the treating medium supplied to the substrate W. The treating medium recovered by the recovery line 2870 may be reused by an external recycling system (not shown).

The side portion 2824b may have an annular ring shape surrounding the support unit 2830.

The side portion 2824b may extend in a vertical direction from the side end of the bottom portion 2824a. The side portion 2824b may extend upward from bottom portion 2824a.

The inclined portion 2824c may extend from the top of the side portion 2824b in a direction toward the central axis of the outer cup 2824. An inner surface of the inclined portion 2824c may be inclined upward to approach the support unit 2830. The inclined portion 2824c may be provided to have a ring shape. During treating of the substrate W, the upper end of the inclined portion 2824c may be positioned higher than the substrate W supported by the support unit 2830.

The support unit 2830 supports the substrate W in the treating space and rotates the substrate W. The support unit 2830 may be a chuck that supports and rotates the substrate W. The support unit 2830 may include a body 2831, a support shaft 2832, and a drive unit 2836. The body 2831 may have an upper surface on which the substrate W is seated. An upper surface of the body 2831 is provided in a generally circular shape when viewed from the top. The upper surface of the body 2831 may have a diameter smaller than that of the substrate W. A suction hole (not shown) is formed in the body 2831 for chucking the substrate W by a vacuum suction method. Alternatively, an electrostatic plate (not shown) is provided on the body 2831 to chuck the substrate W by an electrostatic adsorption method using static electricity. Alternatively, support pins for supporting the substrate W are provided on the body 2831 so that the support pins and the substrate W may physically contact each other to chuck the substrate W.

The support shaft 2832 couples to the body 2831. The support shaft 2832 may engage the lower surface of the body 2831. The support shaft 2832 may be provided so that its longitudinal direction is directed in a vertical direction. The support shaft 2832 is provided to be rotatable by receiving power from the drive unit 2836. The support shaft 2832 is rotated by the rotation of the drive unit 2836, thereby rotating the body 2831. The drive unit 2836 may vary the rotational speed of the support shaft 2832. The drive unit 2836 may be a motor that provides driving force, but is not limited thereto, and may be variously modified with known devices that provide driving force.

A lifting unit 2840 is disposed within the housing 2810. The lifting unit 2840 adjusts the relative height between the treating container 2820 and the support unit 2830. The lifting unit 2840 linearly moves the treating container 2820 in the third direction 6. The lifting unit 2840 may include an inner lifting member 2842 and an outer lifting member 2844. The inner lifting member 2842 may lift and move the inner cup 2822. The outer lift member 2844 may lift and move the outer cup 2824.

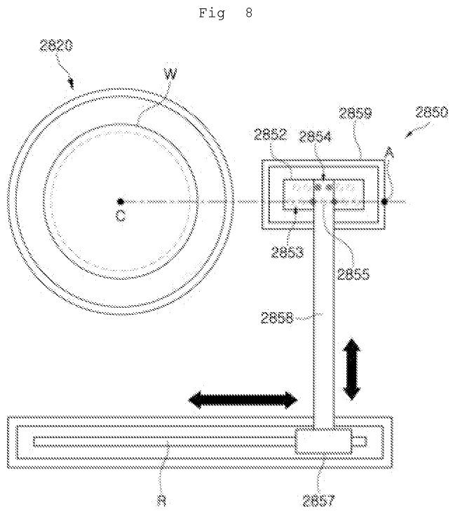

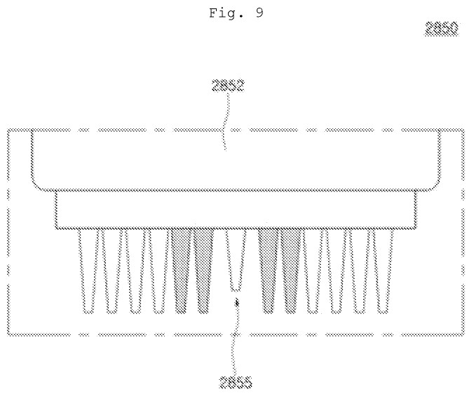

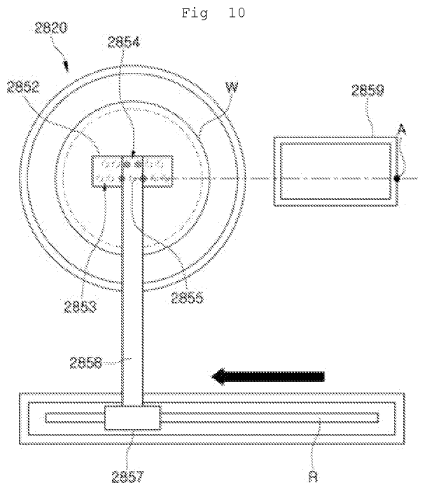

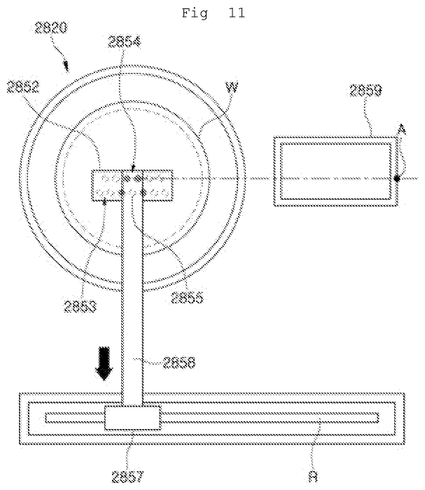

FIG. 8 is a plan view schematically showing a liquid supply unit of FIG. 7 viewed from above; FIG. 9 is a front view schematically showing a state in which the liquid supply unit of FIG. 7 is viewed from the front; FIG. 10 is a view from the top of supplying a treating liquid to a substrate using a first group of nozzles of FIG. 7; and FIG. 11 is a view from the top of supplying a treating liquid to a substrate using a second group of nozzles of FIG. 7. Hereinafter, the liquid supply unit will be described in detail with reference to FIGS. 8 to 11.

The liquid supply unit 2850 may supply liquid to the substrate W supported by the support unit 2830. The liquid supply unit 2850 may supply a treating liquid to the substrate W supported by the support unit 2830. The treating liquid supplied to the substrate W by the liquid supply unit 2850 may be a coating liquid. For example, the coating liquid may be a photoresist (PR). In addition, the liquid supply unit 2850 may supply a pre-wetting liquid to the substrate W supported by the support unit 2830. The pre-wetting liquid supplied by the liquid supply unit 2850 to the substrate W may be a liquid capable of changing the surface properties of the substrate W. For example, the pre-wetting liquid may be a liquid capable of changing the surface properties of the substrate W to have hydrophobic properties. For example, the pre-wetting liquid may be a thinner. As an example, the liquid supply unit 2850 may first discharge the pre-wetting liquid to the center C of the substrate W and then discharge the photoresist to the center C of the substrate W.

The liquid supply unit 2850 may include a nozzle member, an actuator, and a standby port 2859. The nozzle member may supply liquid onto the substrate W. The nozzle member may supply the treating liquid onto the substrate W. The nozzle member may include a body 2852, a first group of nozzles 2853, a second group of nozzles 2854, and a pre-wetting liquid nozzle 2855.

The body 2852 is positioned above the substrate W. The body 2852 may be positioned above the outer cup 2824. The body 2852 may be provided in a substantially rectangular parallelepiped shape, but is not limited thereto, and the body 2852 may be provided in various shapes. A plurality of nozzles may be installed in the body 2852. As an example, the first group of nozzles 2853, the second group of nozzles 2854, and the pre-wetting liquid nozzle 2855 may be installed in the body 2852. As an example, the first group of nozzles 2853, the second group of nozzles 2854, and the pre-wetting liquid nozzle 2855 may be installed on the lower surface of the body 2852. A plurality of channels (not shown) may be provided inside the body 2852 to supply liquid to the first group of nozzles 2853, the second group of nozzles 2854, and the pre-wetting liquid nozzle 2855. A connection member 2858 to be described below may be connected to the body 2852. The connection member 2858 may be connected to the top of the body 2852.

The first group of nozzles 2853 may discharge a treating liquid onto the substrate W. The first group of nozzles 2853 may discharge a coating liquid onto the substrate W. As an example, the coating liquid may be a photoresist. The first group of nozzles 2853 may supply a photoresist to the substrate W in a stream manner.

The first group of nozzles 2853 are coupled to the body 2852. The first group of nozzles 2853 may be coupled to the lower surface of the body 2852. The first group of nozzles 2853 may include a plurality of nozzles. Each of the plurality of nozzles included in the first group of nozzles 2853 may be spaced apart from each other. Each of the plurality of nozzles included in the first group of nozzles 2853 may be arranged along the first direction. The plurality of nozzles included in the first group of nozzles 2853 may be arranged in the first direction to form a first row. The plurality of nozzles included in the first group of nozzles 2853 may discharge photoresists having different compositions from each other onto the substrate W. As an example, each photoresist discharged from the plurality of nozzles included in the first group of nozzles 2853 may have different composition ratios of materials constituting the photoresist.

When the body 2852 is located in the standby port 2859 described later (hereinafter referred to as a “standby position”), the center C of the substrate W may be located on the extension line of the first row where the first group of nozzles 2853 are arranged. When the body 2852 is provided in the standby position, point A of the body 2852 may be located on the extension line of the first row where the first group of nozzles 2853 are arranged.

The second group of nozzles 2854 may discharge a treating liquid onto the substrate W. The second group of nozzles 2854 may discharge a coating liquid onto the substrate W. As an example, the coating liquid may be a photoresist. The second group of nozzles 2854 may supply a photoresist to the substrate W in a stream manner.

The second group of nozzles 2854 are coupled to the body 2852. The second group of nozzles 2854 may be coupled to the lower surface of the body 2852. The second group of nozzles 2854 may include a plurality of nozzles. Each of the plurality of nozzles included in the second group of nozzles 2854 may be spaced apart from each other. Each of the plurality of nozzles included in the second group of nozzles 2854 may be arranged along the first direction.

When viewed from above, a second row may be located above the first row. For example, when viewed from above, the first row may be positioned below the body 2852, and the second row may be positioned above the body 2852. The plurality of nozzles included in the second group of nozzles 2854 may be spaced apart from the plurality of nozzles included in the first group in the second direction. The second direction is defined as a direction perpendicular to the first direction when viewed from above. The plurality of nozzles included in the first group of nozzles 2853 may discharge photoresists having different compositions from each other onto the substrate W. As an example, each photoresist discharged from the plurality of nozzles included in the first group of nozzles 2853 may have different composition ratios of materials constituting the photoresist. In addition, the photoresists discharged from the plurality of nozzles included in the second group of nozzles 2854 and the photoresists discharged from the plurality of nozzles included in the first group of nozzles 2853 may have different compositions.

Moreover, viscosities of the photoresists discharged from the plurality of nozzles included in the first group of nozzles 2853 and the second group of nozzles 2854 may be different by area where each nozzle is located.

For example, in the central area of the body 2852, nozzles (colored nozzles on the drawing) may be disposed to discharge a photoresist having a higher viscosity than in the case of both side areas of the body 2852. By arranging nozzles for discharging a relatively high-viscosity photoresist in the central area of the body 2852, interference with other adjacent nozzle(s) may be prevented. For example, interference with a cleaning liquid injection nozzle provided separately for spraying a cleaning liquid to form a uniform film of the photoresist after applying the photoresist may be prevented.

On the other hand, due to the above configuration, by using the effect of preventing interference with other adjacent nozzle(s), the nozzle member may be disposed adjacent to nozzle(s) for spraying another treating liquid. Accordingly, when a cleaning liquid nozzle injecting a cleaning liquid toward the substrate W is additionally disposed to form a uniform film of photoresist, the cleaning liquid nozzle may be installed in parallel with the liquid supply unit 2850 without additional installation of a separate drive shaft, and thus space utilization may be improved by minimizing an equipment area.

The pre-wetting liquid nozzle 2855 may supply a pre-wetting liquid onto the substrate W.

As an example, the pre-wetting liquid may be thinner. The pre-wetting nozzle 2855 may supply the pre-wetting liquid to the substrate W in a stream manner. The pre-wetting liquid nozzle 2855 is coupled to the body 2852. The pre-wetting liquid nozzle 2855 may be coupled to the lower surface of the body 2852. As an example, the pre-wetting liquid nozzle 2855 may be provided on the first row in which the first group of nozzles 2853 are provided. The pre-wetting liquid nozzle 2855 may be located in the center of the first row. Accordingly, the pre-wetting liquid nozzle 2855 may be provided in the center of the first row, and the nozzles for supplying photoresists may be provided in portions of the first row other than the center of the first row.

Meanwhile, when viewed from the front, the first group of nozzles 2853 and the second group of nozzles 2854 may be arranged in a zigzag manner so that there are no overlapping parts that are not visible (see FIG. 9). In other words, the nozzles disposed in the second row may be disposed apart from the nozzles disposed in the first row by a predetermined distance in the first and second directions. Thus, the number of nozzles constituting the first group of nozzles 2853 and the number of nozzles constituting the second group of nozzles 2854 may be different. As an example, the number of nozzles constituting the first group of nozzles 2853 may be greater than the number of nozzles constituting the second group of nozzles 2854.

Due to the zigzag arrangement in which the first group of nozzles 2853 and the second group of nozzles 2854 are disposed diagonally to each other, the nozzles in the first row and the nozzles in the second row do not overlap each other when looking at the nozzle member from the front, and thus all nozzles may be confirmed without omission. Accordingly, the state of individual nozzles may be checked with just a single shot taken from the front of the nozzle member during a nozzle inspection process to check the state of the nozzles, reducing nozzle inspection time. In addition, due to the zigzag arrangement, the spacing between the nozzles may be minimized, which is advantageous for optimizing the layout of the apparatus.

The actuator may move the nozzle member. The actuator may move the body 2852. The actuator may include a motor 2857 and the connection member 2858. The motor 2857 may be installed on rail R. The motor 2857 may move horizontally on the rail R. The rail R may be provided so that its longitudinal direction is directed in a horizontal direction. The rail R may be provided so that its longitudinal direction faces the first direction. As an example, the motor 2857 may horizontally move the rail R in the first direction. The motor 2857 may move the connection member 2858 in a vertical direction. As an example, the motor 2857 may vertically move the connection member 2858 in the second direction. Meanwhile, the motor 2857 may rotate the connection member 2858 based on an axis parallel to the third direction perpendicular to the first and second directions. The motor 2857 may be provided as a variety of known devices that provide driving force.

The connection member 2858 may be connected to the motor 2857. The connection member 2858 is provided to have a longitudinal direction perpendicular to the rail R when viewed from above. One end of the connection member 2858 may be mounted on the motor 2857 and the other end may be connected to the body 2852. The body 2852 may move horizontally in the first direction and vertically move in the second direction perpendicular to the first direction by the motor 2857 and the connection member 2858. On the other hand, the body 2852 may be rotated based on an axis parallel to the third direction perpendicular to the first and second directions by the motor 2857 and the connection member 2858.

That is, the nozzle member may move horizontally in the first direction and vertically move in the second direction perpendicular to the first direction by the motor 2857 and the connection member 2858. In addition, the nozzle member may be rotated based on an axis parallel to the third direction perpendicular to the first and second directions by the motor 2857 and the connection member 2858. The nozzle member may be moved to a process position and a standby position by the motor 2857 and the connection member 2858. At this time, the process position is a position where the nozzle member faces the substrate W supported by the support unit 2830, and the standby position is a position where the body 2852 is provided to the standby port 2859 described later.

Meanwhile, although not shown in detail, the actuator may further include a lifting motor for vertically moving the connection member 2858 in the first and second directions. The body 2852 may be moved in a direction approaching or away from the substrate W by the lifting motor. As the body 2852 moves toward or away from the substrate W, the flow rate of the treating liquid reaching the substrate W may be controlled.

The standby port 2859 may be located outside of the treating container 2820. The standby port 2859 may be located outside of side portion 2824b of outer cup 2824. A groove may be formed in the standby port 2859. The body 2852 may be positioned in the groove formed in the standby port 2859. When the body 2852 is provided in the standby position, the extension line of the first row formed by the plurality of nozzles included in the first group of nozzle 2853 may coincide with the center C of the substrate W. When the body 2852 is provided in the standby position, point A of the body 2852 may be located on the extension line of the first row formed by the plurality of nozzles included in the first group of nozzle 2853.

Referring to FIG. 10, when liquid is supplied onto the substrate W supported by the support unit 2830 using the first group of nozzles 2853, the motor 2857 moves in the first direction along the length direction of the rail R. Accordingly, the body 2852 located in the standby position moves to a position facing the substrate W. The first group of nozzles 2853 move horizontally to the center C of the substrate W located on the extension line of the first row. Accordingly, liquid is discharged onto the substrate W from one of the nozzles included in the first group of nozzles 2853. As an example, the pre-wetting liquid nozzle 2855 provided on the first row moves horizontally from the standby port 2859 to the center C of the substrate W, and the pre-wetting liquid may be discharged from the pre-wetting liquid nozzle 2855 to the center C of the substrate W. The motor 2857 then horizontally moves the body 2852 in the first direction. Any one of the nozzles included in the first group of nozzles 2853 may move to the center C of the substrate W, and discharge a photoresist having the first composition ratio toward the center C of the substrate W. In addition, another one of the nozzles included in the first group of nozzles 2853 may move to the center C of the substrate W, and discharge a photoresist having the second composition ratio toward the center C of the substrate W.

In addition, the nozzles located in the central region of the body 2852 among the first group of nozzles 2853 may discharge a photoresist having the first viscosity toward the substrate W. In addition, the nozzles located on the side regions of the body 2852 among the first group of nozzles 2853 may discharge a photoresist having the second viscosity toward the substrate W. At this time, the first viscosity has a higher viscosity than the second viscosity.

Referring to FIG. 11, the motor 2857 moves the body 2852 in the second direction perpendicular to the first direction. When any one of the nozzles included in the second group of nozzles 2854 moves to the center C of the substrate W, a photoresist having the third composition ratio may be discharged toward the center C of the substrate W. The motor 2857 then moves the body 2852 in the first direction, and when another one of the nozzles included in the second group of nozzles 2854 moves to the center C of the substrate W, a photoresist having the fourth composition ratio may be discharged toward the center C of the substrate W.

In addition, the nozzles located in the central region of the body 2852 among the second group of nozzles 2854 may discharge a photoresist having the third viscosity toward the substrate W. In addition, the nozzles located on the side regions of the body 2852 among the second group of nozzles 2854 may discharge a photoresist having the fourth viscosity toward the substrate W. At this time, the third viscosity has a higher viscosity than the fourth viscosity. In addition, the first viscosity has a higher viscosity than the fourth viscosity. The first viscosity and the third viscosity may be the same. The first viscosity and the third viscosity may be different.

When liquid supply on the substrate W using the nozzle member is completed, the motor 2857 moves the body 2852 to be positioned in the standby port 2859.

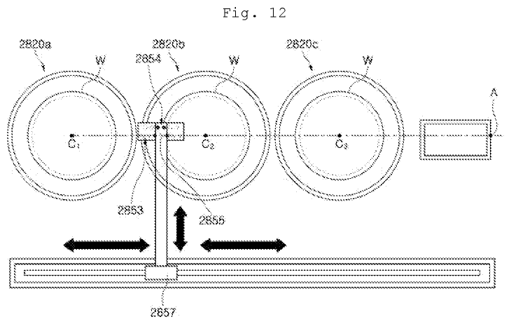

FIG. 12 is a view schematically showing a state in which the nozzle member is positioned on the liquid treating chamber 280 of FIG. 3. Referring to FIG. 12, the liquid treating chamber 280 may include a plurality of treating containers arranged in a line. The standby port 2859 may be located on one side of the treating containers arranged in a row. As an example, the liquid treating chamber 280 may include a first treating container 2820a, a second treating container 2820b, and a third treating container 2820c, and the standby port 2859 may be located outside the third treating container 2820c. Alternatively, the standby port 2859 may be located outside the first treating container 2820a. When the body 2852 is provided in standby position, the extension line of the first row formed by the plurality of nozzles included in the first group of nozzles 2853 may coincide with the centers C1, C2, and C3 of the substrates W supported by the support unit inside individual treating containers. The nozzle member may be moved in a direction in which the treating containers are arranged by the actuator.

When liquid is supplied onto the substrate W existing in the first treating container 2820a using the first group of nozzles 2853, the motor 2857 moves in the first direction along the length direction of the rail R. The first group of nozzles 2853 move horizontally to the center C1 of the substrate W located on the extension line of the first row. Accordingly, each of the nozzles included in the first group of nozzles 2853 discharges the liquid toward the substrate W existing in the first treating container 2820a. The motor 2857 then moves body 2852 in the second direction perpendicular to the first direction. The motor 2857 vertically moves the body 2852 so that the center C1 of the substrate W is located on the extension line of the second row formed by the second group of nozzles 2854. Accordingly, each of the nozzles included in the second group of nozzles 2854 discharges the liquid toward the substrate W existing in the first treating container 2820a.

When liquid is supplied onto the substrate W existing in the second treating container 2820b using the first group of nozzles 2853, the motor 2857 moves in the first direction along the length direction of the rail R. The first group of nozzles 2853 move horizontally to the center C2 of the substrate W located on the extension line of the first row. Accordingly, each of the nozzles included in the first group of nozzles 2853 discharges the liquid toward the substrate W existing in the second treating container 2820b. The motor 2857 then moves body 2852 in the second direction perpendicular to the first direction. The motor 2857 vertically moves the body 2852 so that the center C2 of the substrate W is located on the extension line of the second row formed by the second group of nozzles 2854. Accordingly, each of the nozzles included in the second group of nozzles 2854 discharges the liquid toward the substrate W existing in the second treating container 2820b.

When liquid is supplied onto the substrate W existing in the third treating container 2820c using the first group of nozzles 2853, the motor 2857 moves in the first direction along the length direction of the rail R. The first group of nozzles 2853 move horizontally to the center C3 of the substrate W located on the extension line of the first row. Accordingly, each of the nozzles included in the first group of nozzles 2853 discharges the liquid toward the substrate W existing in the third treating container 2820c. The motor 2857 then moves body 2852 in the second direction perpendicular to the first direction. The motor 2857 vertically moves the body 2852 so that the center C3 of the substrate W is located on the extension line of the second row formed by the second group of nozzles 2854. Accordingly, each of the nozzles included in the second group of nozzles 2854 discharges the liquid toward the substrate W existing in the third treating container 2820c.

When liquid supply on the substrate W using the nozzle member is completed, the motor 2857 moves the body 2852 to be positioned in the standby port 2859.

According to the above-described embodiment of the present disclosure, photoresists having various composition ratios and various viscosities may be supplied onto the substrate W using one nozzle member. In addition, by arranging the plurality of nozzles in two rows, the space occupied by the nozzle member in the liquid supply unit may be minimized. In addition, by arranging the plurality of nozzles in two rows, it is possible to satisfy demand for improving productivity of substrates as substrates become larger, thereby increasing substrate treating efficiency. As the first group of nozzles 2853 move in the first direction and the second group of nozzles 2854 move in the first direction and/or the second direction, when the liquid is discharged onto the substrate W, the path in which the nozzle member moves is simplified, so that the substrate treating efficiency may be improved. In addition, because the moving path of the nozzle member is simplified, interference with other components included in the liquid treating chamber 280 may be minimized. In addition, the first row and the second row are spaced apart from each other by a predetermined distance in the first and second directions when viewed from above. That is, the nozzles disposed in the first row and the nozzles disposed in the second row are spaced diagonally from each other. Therefore, when the nozzle member is viewed from the front, the nozzles of the first group and the nozzles of the second group do not overlap each other. In other words, by arranging the first row of nozzles and the second row of nozzles in a zigzag manner, all nozzles constituting the nozzle member may be observed without omission when the nozzle member is observed from the front. Accordingly, since images of all the nozzles constituting the nozzle member may be obtained using only a single shot in the nozzle inspection process to check the defective state of the nozzle, nozzle maintenance time may be reduced.

Referring back to FIG. 7, the exhaust line 2880 may be provided outside the liquid treating chamber 280. A pressure reducing unit (not shown) is installed in the exhaust line 2880. The exhaust line 2880 exhausts the atmosphere inside the treating space by means of the pressure reducing unit. The exhaust line 2880 may couple with the treating container 2820. Alternatively, the exhaust line 2880 may be coupled to the bottom of outer cup 2824. When viewed from the top, the exhaust line 2880 may be positioned to overlap the inner cup 2822.

An air current supply unit 2860 supplies air current to the internal space of the housing 2810. The air current supply unit 2860 may supply a descending air current to the internal space. The air current supply unit 2860 may supply air currents with temperature and/or humidity controlled to the internal space. The air current supply unit 2860 may be installed in the housing 2810. The air current supply unit 2860 may be installed above the treating container 2820 and the support unit 2830. The air current supply unit 2860 may include a fan, an air current supply line, and a filter. An air current supply line may supply an external air current in which temperature and/or humidity are controlled to the internal space. A filter may be installed in the air current supply line. The filter may remove impurities from external air current flowing in the air current supply line. When the fan is driven, the air current from the outside supplied by the air current supply line may be uniformly delivered to the internal space.

Referring back to FIGS. 1 to 3, the developing block 20b has the transport chamber 220, the buffer chamber 240, the heat treating chamber 260, and the liquid treating chamber 280. Since the transport chamber 220, the buffer chamber 240, the heat treating chamber 260, and the liquid treating chamber 280 of the developing block 20b are provided in substantially similar structures and arrangements to the transport chamber 220, the buffer chamber 240, the heat treating chamber 260, and the liquid treating chamber 280 of the coating block 20a, description thereof is omitted. However, all of the liquid treating chambers 280 of the developing block 20b perform a developing process of developing the substrate W by supplying a developer solution in the same way.

The interface module 30 connects the treating module 20 and an external exposure device 40.

The interface module 30 includes an interface frame 320, an additional process chamber 340, an interface buffer 360, and a transport member 380.

The interface frame 320 provides an internal space. A fan filter unit may be provided at the upper end of the interface frame 320 to form a descending air current in the internal space. The additional process chamber 340, the interface buffer 360, and the transport member 380 are provided in the internal space of the interface frame 320.

The additional process chamber 340 may perform a predetermined additional process before the substrate W, which has been treated in the coating block 20a, is transferred to the exposure device 40. Alternatively, the additional process chamber 340 may perform a predetermined additional process before the substrate W, which has been treated in the exposure device 40, is transferred to the developing block 20b. As an example, the additional process may be an edge exposure process of exposing the edge area of the substrate W, an upper surface cleaning process of cleaning the upper surface of the substrate W, or a lower surface cleaning process of cleaning the lower surface of the substrate W. A plurality of additional process chambers 340 may be provided, and the plurality of additional process chambers 340 may be provided to be stacked on top of each other.

The additional process chambers 340 may all be provided to perform the same process. Alternatively, some of the additional process chambers 340 may be provided to perform different processes.

The interface buffer 360 provides a space in which the substrate W transported between the coating block 20a, the additional process chamber 340, the exposure device 40, and the developing block 20b temporarily stays during transport. A plurality of interface buffers 360 may be provided, and the plurality of interface buffers 360 may be provided in a stacked manner. As an example, the additional process chamber 340 may be disposed on one side of the extension of the transport chamber 220 in the longitudinal direction, and the interface buffer 360 may be disposed on the other side.

The transport member 380 transfers the substrate W between the coating block 20a, the additional process chamber 340, the exposure device 40, and the developing block 20b. The transport member 380 may be provided as one or a plurality of robots. As an example, the transport member 380 includes a first robot 3820, a second robot 3840, and a third robot (not shown). The first robot 3820 transfers the substrate W between the coating block 20a, the additional process chamber 340, and the interface buffer 360. The second robot 3840 transfers the substrate W between the interface buffer 360 and the exposure device 40. The third robot (not shown) transfers the substrate W between interface buffer 360 and the developing block 20b. The first robot 3820, the second robot 3840, and the third robot (not shown) each include a hand on which the substrate W is placed. The hand may be provided to move forward and backward, rotate about an axis parallel to the third direction 6, and move along the third direction 6. The hands of the first robot 3820, the second robot 3840, and the third robot (not shown) may all be provided in the same or similar shape as the transport hand 2240 of the transport robot 224. Alternatively, the hand of the robot that directly transfers the substrate W to the cooling plate 2642 of the heat treating chamber is provided in the same or similar shape as the transport hand 2240 of the transport robot 224, while the other robot hand(s) may be provided in a different shape.

The above detailed description is illustrative of the present disclosure. In addition, the foregoing is intended to illustrate and describe preferred embodiments of the present disclosure, and the present disclosure may be used in many different combinations, modifications and environments. That is, changes or modifications are possible within the scope of the concept of the invention disclosed in this specification, within the scope equivalent to the written disclosure and/or within the scope of skill or knowledge in the art. The written embodiments describe the best state for implementing the technical idea of the present disclosure, and various changes required in the specific application field and required for the specific use of the present disclosure are also possible. Therefore, the above detailed description of the invention is not intended to limit the present disclosure to the disclosed embodiments. Furthermore, the appended claims should be construed to cover other embodiments as well.

What is claimed is:

1. A liquid supply unit, comprising:
a nozzle member configured to supply a treating liquid onto a substrate; and
an actuator configured to move the nozzle member,
wherein the nozzle member comprises:
a body;
a first group of nozzles coupled to the body and arranged along a first direction so that the nozzles form a first row; and
a second group of nozzles coupled to the body and arranged along the first direction so that the nozzles form a second row,
wherein the first row and the second row are spaced apart from each other by a predetermined distance in the first direction and a second direction perpendicular to the first direction when viewed from the above of the liquid supply unit, so that the first group of nozzles and the second group of nozzles do not overlap each other when the nozzle member is viewed from the front of the liquid supply unit.

2. The liquid supply unit of claim 1, wherein the actuator linearly moves the body in the first direction and the second direction, and moves the body up and down in a third direction perpendicular to the first and second directions.

3. The liquid supply unit of claim 2, wherein the nozzles constituting the nozzle member discharge treating liquids having different viscosities for respective areas where individual nozzles are located.

4. The liquid supply unit of claim 3, wherein the nozzles include a plurality of nozzles disposed in a central region of the body and a plurality of nozzles disposed on each side region of the central region, and the nozzles disposed in the central region of the body discharge a treating liquid having a higher viscosity than a treating liquid discharged by the nozzles disposed on the side regions of the central region.

5. The liquid supply unit of claim 2, further comprising:
a standby port,
wherein when the body is placed in the standby port, a center of the substrate supported by a support unit is located on an extension line of the first row.

6. The liquid supply unit of claim 2, wherein the actuator moves the body along the first direction to supply treating liquids to the substrate using the first group of nozzles.

7. The liquid supply unit of claim 6, wherein the actuator moves the body along the first direction and the second direction to supply treating liquids to the substrate using the second group of nozzles.

8. The liquid supply unit of claim 1, wherein the nozzle member further comprises:
a pre-wetting liquid nozzle located in a center of the first row and supplying a pre-wetting liquid onto the substrate.

9. The liquid supply unit of claim 1, wherein the number of the first group of nozzles is greater than the number of the second group of nozzles.

10. The liquid supply unit of claim 1, wherein the treating liquid is a coating liquid.

11. A substrate treating apparatus, comprising:
a treating container configured to have a treating space therein;
a support unit configured to support a substrate in the treating space; and
a liquid supply unit configured to supply a treating liquid onto the substrate,
wherein the liquid supply unit comprises:
a nozzle member movably provided by an actuator,
wherein the nozzle member comprises:
a body;
a first group of nozzles coupled to the body and arranged along a first direction so that the nozzles form a first row; and
a second group of nozzles coupled to the body and arranged along the first direction so that the nozzles foam a second row,
wherein the first row and the second row are spaced apart from each other by a predetermined distance in the first direction and a second direction perpendicular to the first direction when viewed from the above of the liquid supply unit, so that the first group of nozzles and the second group of nozzles do not overlap each other when the nozzle member is viewed from the front of the liquid supply unit.

12. The substrate treating apparatus of claim 11, wherein the actuator linearly moves the body in the first direction and the second direction, and moves the body up and down in a third direction perpendicular to the first and second directions.

13. The substrate treating apparatus of claim 12, wherein the nozzles constituting the nozzle member discharge treating liquids having different viscosities for respective areas where individual nozzles are located, and
the nozzles include a plurality of nozzles disposed in a central region of the body and a plurality of nozzles disposed on each side region of the central region, and the nozzles disposed in the central region of the body discharge a treating liquid having a higher viscosity than a treating liquid discharged by the nozzles disposed on the side regions of the central region.

14. The substrate treating apparatus of claim 12, wherein the liquid supply unit further comprises:
a standby port,
wherein when the body is placed in the standby port, a center of the substrate is located on an extension line of the first row.

15. The substrate treating apparatus of claim 12, wherein the actuator moves the body along the first direction to supply treating liquids to the substrate using the first group of nozzles, and
moves the body along the first direction and the second direction to supply treating liquids to the substrate using the second group of nozzles.

16. The substrate treating apparatus of claim 11, wherein the treating liquid is a photoresist.

17. Substrate treating equipment, comprising:
an index module where a substrate is carried in or out; and
a treating module configured to include a substrate treating apparatus performing a liquid treating process on the substrate,
wherein the substrate treating apparatus comprises:
treating containers arranged in a line and having support units for supporting substrates disposed in an internal space thereof; and
a liquid supply unit supplying a treating liquid onto the substrate,
wherein the liquid supply unit comprises:
a nozzle member that is moved, by an actuator, in a direction in which the treating containers are arranged,
wherein the nozzle member comprises:
a body;
a first group of nozzles coupled to the body and arranged along a first direction so that the nozzles form a first row; and
a second group of nozzles coupled to the body and arranged along the first direction so that the nozzles form a second row,
wherein the first row and the second row are spaced apart from each other by a predetermined distance in the first direction and a second direction perpendicular to the first direction when viewed from the above of the liquid supply unit, so that the first group of nozzles and the second group of nozzles do not overlap each other when the nozzle member is viewed from the front of the liquid supply unit.

18. The substrate treating equipment of claim 17, wherein the actuator linearly moves the body in the first direction and the second direction, and moves the body up and down in a third direction perpendicular to the first and second directions.

19. The substrate treating equipment of claim 18, wherein the nozzles constituting the nozzle member discharge treating liquids having different viscosities for respective areas where individual nozzles are located, and
the nozzles include a plurality of nozzles disposed in a central region of the body and a plurality of nozzles disposed on each side region of the central region, and the nozzles disposed in the central region of the body discharge a treating liquid having a higher viscosity than a treating liquid discharged by the nozzles disposed on the side regions of the central region.

20. The substrate treating equipment of claim 18, wherein the liquid supply unit further comprises:
a standby port disposed on a side of the treating containers,
wherein when the body is placed in the standby port, a center of the substrate is located on an extension line of the first row, and
the actuator moves the body along the first direction to supply treating liquids to the substrate using the first group of nozzles, and moves the body along the first direction and the second direction to supply treating liquids to the substrate using the second group of nozzles.
